(19) United States
(12) Patent Application Publication
(10) Pub. No.: US 2026/0005040 A1
(43) Pub. Date: Jan. 1, 2026

(54) PROCESS GAS MONITORING APPARATUS, VOLATILIZATION VESSEL, SUBSTRATE PROCESSING APPARATUS, AND METHOD

(71) Applicant: ASM IP Holding B.V., Almere (NL)

(72) Inventors: SunJoo Park, Seoul (KR); HakJoo Lee, Hwaseong-Si (KR); WanGyu Lim, Hwaseong-si (KR); SeungMin Shin, Incheon (KR); Junli Li, Suwon (KR)

(21) Appl. No.: 19/249,508

(22) Filed: Jun. 25, 2025

Related U.S. Application Data
(60) Provisional application No. 63/664,825, filed on Jun. 27, 2024.

(51) Int. Cl. H01L 21/67

(52) U.S. Cl. CPC H01L 21/67017

(57) ABSTRACT

This disclosure relates to a process gas monitoring apparatus, a volatilization vessel, a substrate processing apparatus, and a method for monitoring supply of process gas into a process chamber. The process gas comprises a chemical substance thermally decomposable to form a decomposition product, and the method comprises measuring concentration of the decomposition product in the process gas.

### CROSS-REFERENCE TO RELATED APPLICATIONS

This application claims priority to U.S. Provisional Patent Application Ser. No. 63/664,825 filed Jun. 27, 2024 titled PROCESS GAS MONITORING APPARATUS, VOLATILIZATION VESSEL, SUBSTRATE PROCESSING APPARATUS, AND METHOD, the disclosure of which is hereby incorporated by reference in its entirety.

### TECHNICAL FIELD

This disclosure generally relates to the fields of microfabrication and nanofabrication. In particular, the present disclosure relates to the field of semiconductor manufacturing technology, for example, the fabrication of integrated circuits.

### BACKGROUND

The semiconductor manufacturing industry has long been characterized by its rapid technological advancements and the increasing demand for more efficient and powerful electronic devices. As the industry strives to meet these demands, there is a growing need to develop manufacturing processes that are not only cost-effective but also environmentally sustainable.

One of the critical steps in semiconductor fabrication is the deposition of thin films, such as silicon nitride (SiN), which are essential for the construction of various electronic components. In some cases, plasma-enhanced processes, such as plasma-enhanced atomic layer deposition (PEALD), may be used to deposit SiN. Plasma-enhanced processes can be operated at relatively low temperatures and/or exhibit relatively high deposition rates.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

According to a first aspect, a process gas monitoring apparatus for monitoring supply of process gas comprising a chemical substance thermally decomposable to form a decomposition product is provided. The process gas monitoring apparatus comprises a gas analyzer configured to generate a concentration signal indicative of concentration of the decomposition product in the process gas. The process gas monitoring apparatus further comprises a process gas control unit configured to receive the concentration signal and to generate a control signal if the concentration of the decomposition product indicated by the concentration signal is greater than a predetermined concentration threshold value.

According to a second aspect, a volatilization vessel for holding a chemical substance thermally decomposable to form a decomposition product is provided. The volatilization vessel comprises a shell defining an inner cavity for holding the chemical substance in condensed form, a gas analyzer configured to generate a concentration signal indicative of concentration of the decomposition product in the inner cavity, and a process gas control unit configured to receive the concentration signal and to generate a control signal if the concentration of the decomposition product indicated by the concentration signal is greater than a predetermined concentration threshold value.

According to a third aspect, a substrate processing apparatus is provided. The substrate processing apparatus comprises a process chamber for holding at least part of a substrate; a process gas inlet for receiving process gas from a volatilization vessel; a process gas delivery line extending between the process gas inlet and the process chamber for transferring the process gas into the process chamber, the process gas comprising a chemical substance thermally decomposable to form a decomposition product; a gas analyzer configured to generate a concentration signal indicative of concentration of the decomposition product in the process gas; and a process gas control unit configured to receive the concentration signal and to generate a control signal if the concentration of the decomposition product indicated by the concentration signal is greater than a predetermined concentration threshold value.

According to a fourth aspect, a method for monitoring supply of process gas into a process chamber is provided. The method comprises providing the process gas to be supplied into the process chamber, the process gas comprising a chemical substance thermally decomposable to form a decomposition product; measuring concentration of the decomposition product in the process gas; and generating a control signal if the concentration of the decomposition product is greater than a predetermined concentration threshold value.

In some embodiments, the volatilization vessel is implemented as a vaporization vessel.

In some embodiments, the volatilization vessel comprises the chemical substance, the chemical substance held in the inner cavity.

In some embodiments, the decomposition product has a first molecular weight, and the chemical substance has a molecular weight lower than the first molecular weight.

In some embodiments, the chemical substance comprises a halogenated silane.

In some embodiments, the substrate processing apparatus comprises a vessel heater for heating the volatilization vessel.

In some embodiments, the vessel heater is configured to maintain temperature of the chemical substance inside the volatilization vessel in a temperature range from 0° C. to 150° C.

In some embodiments, the gas analyzer is configured to measure the concentration of the decomposition product in the process gas within the process gas delivery line.

In some embodiments, the gas analyzer is configured to measure the concentration of the decomposition product in the process gas within the volatilization vessel.

In some embodiments, the gas analyzer is configured to measure the concentration of the decomposition product by one or more in-line measurements and/or one or more on-line measurements.

In some embodiments, the substrate processing apparatus comprises an alarm control unit configured to receive the control signal and to raise an alarm in response to the control signal.

In some embodiments, the process gas delivery line comprises a process gas bypass valve for steering the process gas past the process chamber, the substrate processing apparatus comprises a vessel unload control unit operatively coupled with the process gas bypass valve and configured to receive the control signal, and the vessel unload control unit is configured to hold the process gas bypass valve open in response to the control signal for emptying the volatilization vessel.

In some embodiments, the substrate processing apparatus comprises a storage vessel for storing the chemical substance in condensed form and a refill line fluidically coupled with the storage vessel for transferring the chemical substance from the storage vessel to the volatilization vessel.

In some embodiments, the substrate processing apparatus comprises a second process gas inlet for receiving process gas from a second volatilization vessel.

In some embodiments, the substrate processing apparatus is implemented as a vacuum deposition apparatus, such as a chemical vapor deposition apparatus, for example, a cyclic chemical vapor deposition apparatus, such as an atomic layer deposition apparatus, e.g., a temporal atomic layer deposition apparatus.

In some embodiments, providing the process gas comprises holding the chemical substance inside a volatilization vessel and volatilizing the chemical substance to form the process gas.

In some embodiments, volatilizing the chemical substance comprises maintaining temperature of the chemical substance in a temperature range from 0° C. to 150° C.

In some embodiments, measuring concentration of the decomposition product comprises measuring the concentration of the decomposition product by one or more in-line measurements and/or measuring the concentration of the decomposition product by one or more on-line measurements.

In some embodiments, measuring concentration of the decomposition product comprises measuring the concentration of the decomposition product within the volatilization vessel.

In some embodiments, measuring concentration of the decomposition product comprises measuring the concentration of the decomposition product downstream of the volatilization vessel and upstream of the process chamber.

In some embodiments, an alarm is raised in response to the control signal.

In some embodiments, the volatilization vessel is emptied in response to the control signal.

In some embodiments, the volatilization vessel is refilled in response to the control signal.

In some embodiments, use of a second volatilization vessel is initiated in response to the control signal for supplying process gas into the process chamber.

In some embodiments, the process gas is fed into the process chamber if the concentration of the decomposition product is less than or equal to the predetermined concentration threshold value.

### DESCRIPTION OF THE DRAWINGS

A more complete understanding of the embodiments of the present disclosure may be derived by referring to the detailed description and claims when considered in connection with the following illustrative figures:

FIG. 1 illustrates a process gas monitoring apparatus,

FIG. 2 shows volatilization vessel,

FIG. 3 depicts substrate processing apparatus, and

FIG. 4 illustrates a method for monitoring supply of process gas into a process chamber.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

The illustrations presented herein are not meant to be actual views of any particular material, structure, or device, but are merely idealized representations that are used to describe embodiments of the disclosure.

For clarity and brevity, consistent reference numerals may be used throughout the figures for corresponding, similar, and/or identical elements.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail or omitted entirely. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

In this specification, a “chemical substance” may refer to a form of matter having constant chemical composition and characteristic properties. Additionally or alternatively, a chemical substance may refer to a material with a specific chemical identity that distinguishes it from other materials and is known by a common or scientific name. A chemical substance may comprise one or more molecules with an identical molecular structure. Herein, a “molecule” may refer to a group of atoms bonded together, representing the smallest fundamental unit of a chemical substance that can take part in a chemical reaction.

Throughout this specification, the term “thermally decomposable” may refer to a characteristic of a chemical substance that enables it to break down into simpler chemical structures when subjected to heat. Additionally or alternatively, a thermally decomposable substance may refer to a compound that undergoes a chemical change and decomposes into two or more different substances upon heating. A thermally decomposable chemical substance may exhibit this property due to the instability of its molecular structure at elevated temperatures. Herein, “decomposition” may refer to the process by which a chemical substance breaks down into its constituent parts or into simpler chemical substances as a result of thermal energy. Additionally or alternatively, decomposition may refer to the separation of a chemical substance into elements or simpler chemical substances through an endothermic reaction.

In this disclosure, a “threshold value” may refer to the point at which a particular effect occurs when a numerical value reaches a certain level. Additionally or alternatively, a threshold value may refer to a limit that, when surpassed, initiates a change in the state or condition of the system. In some embodiments, a threshold value may be implemented as a numerical value or as a ratio, or the like. Further, a “predetermined” threshold value may refer to a limit that has been established prior to a process or operation, based on empirical data, theoretical calculations, or regulatory standards. Additionally or alternatively, a predetermined threshold value may refer to a threshold value that is repeatedly, recurrently, intermittently, periodically updated during a process or operation to account for changes in a standard operation state of a system. Therefore, a “predetermined concentration threshold value” may refer to a predetermined threshold value associated with a concentration of a gaseous substance. Additionally or alternatively, a predetermined concentration threshold value may refer to a predetermined threshold value associated with a concentration of the decomposition product in a process gas. Additionally or alternatively, a predetermined concentration threshold value may refer to a quantifiable level of concentration, determined through empirical data or theoretical calculation, which triggers a response or action when exceeded.

Throughout this specification, a “vessel” may refer to a container suitable or configured for storing and/or holding one or more chemical substances. In some embodiments, said one or more chemical substances may comprise solid chemical substance(s), liquid chemical substance(s), and/or gaseous chemical substance(s). Further, a “volatilization vessel” may refer to a vessel suitable or configured for volatilizing a chemical substance. Additionally or alternatively, a volatilization vessel may refer to a vessel suitable for or configured to supply a chemical substance in gaseous form to a substrate processing apparatus. Additionally or alternatively, a volatilization vessel may refer to a vessel comprising an outer wall defining a cavity for storing and/or holding a substance and a gas outlet for allowing said substance to exit said cavity in gaseous form. In some embodiments, a volatilization vessel may comprise one or more vessel temperature control elements, such as one or more heating elements, and/or one or more cooling elements; and/or one or more heat dissipation elements; and/or one or more insulation elements. In some embodiments, a volatilization vessel may comprise one or more fluid inlets. In some such embodiments, said one or more fluid inlets may comprise a carrier gas inlet. In some embodiments, a volatilization vessel may be implemented as a sublimation vessel and/or as a vaporization vessel. In some embodiments, a volatilization vessel may comprise one or more sensors, such as one or more temperature sensors, and/or one or more pressure sensors. In some embodiments, a volatilization vessel may comprise one or more valves, such as one or more flow control valves.

In this specification, the term “gaseous” may refer to any gas-like form, e.g., a gas, a vapor, or a plasma, whereas the term “condensed” may refer to any non-gaseous form, e.g., a liquid or a solid.

In this disclosure, a “vaporization vessel” may refer to a volatilization vessel suitable or configured for vaporizing, i.e., evaporating and/or boiling, a liquid chemical substance. Additionally or alternatively, a vaporization vessel may refer to a volatilization vessel suitable for or configured to supply a gaseous chemical substance formed by vaporization of a liquid chemical substance to a substrate processing apparatus. In some embodiments, a vaporization vessel may comprise a gas outlet for allowing a substance to exit said cavity in gaseous form; one or more fluid inlets, said one or more fluid inlets comprising, for example, a carrier gas inlet; and/or a carrier gas conduit extending inwards from said carrier gas inlet, said carrier gas conduit configured to direct carrier gas introduced into said vaporization vessel via said carrier gas inlet below a surface of a liquid substance during use of said vaporization vessel.

Herein, a “process chamber” may refer to a chamber suitable for or configured to enable performing a process on a substrate. Additionally or alternatively, a process chamber may refer to a vacuum chamber within which a process may be performed. A process chamber may comprise one or more process stations.

Herein, a “process station” may refer to a location suitable for or configured to hold at least part of a substrate so that a process may be performed on the substrate. Additionally or alternatively, a process station may refer to a portion of a process chamber. In some embodiments, individual process stations of a process chamber may be arranged in gas isolation from each other or configured to be in gas isolation from each other while one or more substrates are processed inside one or more of the individual process stations. In such embodiments, individual process stations of a process chamber may be arranged in gas isolation by way of physical barriers, and/or gas bearings, and/or gas curtains. In some embodiments, after or concurrently with the placement of a substrate in a process station, said process station may be arranged in gas isolation. In some embodiments, after a substrate has been processed in a process station, said process station may be brought out of gas isolation such that said substrate may be removed from the process station. Typically, a plurality of substrates may be placed in a shared intermediate space of a process chamber for moving individual substrates of said plurality of substrates from process station to another.

In this disclosure, a “substrate” may refer to any underlying material or materials that may be used to form, or upon which, a device, a circuit, or a film may be formed. Additionally or alternatively, a substrate may refer to an object including a bulk material, such as silicon (e.g., single-crystal silicon), other Group IV materials, such as germanium, or compound semiconductor materials, such as GaAs, and optionally one or more layers overlying or underlying the bulk material and/or various structures, such as recesses, vias, lines, and the like formed within or on at least a portion of a layer of the substrate. In some embodiments, a substrate may comprise a semiconductor wafer or an elongate sheet-shaped film.

Herein, a “layer” or “film” may refer to a structure having a certain thickness formed on a surface. A layer may be continuous or discontinuous. A film or layer may or may not be constituted by a discrete single film or layer having certain characteristics or multiple films or layers. A boundary between adjacent films or layers may or may not be clear and may or may not be established based on physical, chemical, and/or any other characteristics, formation processes or sequences, and/or functions or purposes of the adjacent films or layers. A layer or film may or may not comprise pinholes. A layer of film may or may not be porous.

Throughout this specification, the term “measurement” may refer to the process of obtaining a quantitative or qualitative value that represents a characteristic of an object or phenomenon. In some embodiments, a measurement may be obtained through direct or indirect methods and may involve the use of one or more measurement instruments. Further, the term “in-line” may refer to a process or component that is integrated within a production line or system, such that it operates concurrently with a process flow, whereas the term “on-line” may refer to a process or component that operates on a sample stream diverted from the process flow.

As such, on the one hand, an “in-line measurement” may refer to a measurement taken directly within a production line or system, without interrupting or diverting a process flow. Additionally or alternatively, an in-line measurement may refer to a measurement that is performed continuously or at regular intervals during the operation of a production process. In some embodiments, an in-line measurement may involve the use of sensors or instruments that are installed at specific points along a production line.

On the other hand, an “on-line measurement” may refer to a measurement that is performed on a sample taken from a continuous process stream without stopping or interrupting a process flow. Additionally or alternatively, an on-line measurement may refer to a measurement that is conducted via a bypass, which may allow analysis under less harsh and/or demanding conditions than those present in a process to be measured. In some embodiments, an on-line measurement may involve the use of automated sampling systems that divert a portion of the process stream into an analytical instrument. This allows for continuous monitoring and analysis of the process while maintaining the integrity of the measured process.

In this specification, “etching” may refer to removing material from a substrate. Additionally or alternatively, etching may refer to forming volatile species, for example, via one or more chemical reactions. Further, “dry etching” may refer to removal of material from a substrate using one or more gaseous substances. In some embodiments, a dry etching process may involve introducing one or more gaseous substances into a process chamber. In some embodiments, dry etching may involve the use of active species, e.g., active species formed in a plasma. Naturally, a “dry etching apparatus” may then refer to a system suitable or configured for performing dry etching. In some embodiments, a dry etching apparatus may comprise a process chamber to contain the substrate and gases, a gas delivery system, and controls for temperature and pressure to facilitate the dry etching.

Throughout this specification, a “species” may refer to a chemical species, such as a chemical compound or a molecular structural unit of a solid array, or a molecular entity. Additionally or alternatively, species may refer to one or more structurally distinct atoms, molecules, ions, radicals, or complexes. Herein, an “ion” may refer to an atomic or molecular particle possessing a net electric charge, and/or a “radical” may refer to an atomic or molecular particle possessing an unpaired electron. Further, “active species” may refer to unstable species formed in plasma, via interactions with catalytic material(s) at elevated temperatures, and/or by other suitable means. Additionally or alternatively, active species may refer to ions and/or radicals.

In this specification, a “chemical vapor deposition process” or “CVD process” may refer to a coating process, wherein one or more gaseous compounds decompose to deposit a layer onto a substrate. Further, a “cyclic chemical vapor deposition process” or “cyclic CVD process” may refer to a CVD process comprising sequentially and/or cyclically providing precursors, and/or reactants, and/or active species to deposit said layer onto said substrate.

Throughout this specification, an “atomic layer deposition process” or “ALD process” may refer to a cyclic CVD process, comprising purging a process chamber or a process station between provision of precursors, and/or reactants, and/or active species. Typically, purging may be accomplished by flushing said process chamber or process station with an inert gas. Additionally or alternatively, an “atomic layer deposition process” or “ALD process” may refer to a cyclic CVD process suitable for or configured to deposit a conformal layer, e.g., a layer with a step coverage (SC) of at least 95%, or 99%, or about 100% for a feature with an aspect ratio (AR) of 3:1, or 5:1, or 10:1, onto a substrate. The term “atomic layer deposition”, as used herein, may or may not also refer to processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Further, a “temporal atomic layer process” or “temporal ALD process” may refer to an ALD process, wherein the process of purging a process station comprises a temporal purging step during which provision of precursors, and/or reactants, and/or active species is discontinued. Additionally or alternatively, a “temporal atomic layer process” or “temporal ALD process” may refer to an ALD process, wherein a substrate onto which a layer is deposited is held immobile during deposition.

In this specification, a “process” may refer to a series of one or more steps, leading to an end result. Additionally, a “step” may refer to a measure taken in order to achieve one or more pre-defined end results. Generally, a process may be a single-step or a multistep process. Additionally, a process may be divisible to a plurality of sub-processes, wherein individual sub-processes of such plurality of sub-processes may or may not share common steps.

In this specification, the term “unit” may refer to a device suitable for or configured to execute at least one specific process. A unit may typically comprise one or more constituents, each of which can be categorized as a component that is part of the said unit. Generally, a unit may comprise any components that are essential and/or advantageous for executing the specific process(es) for which the unit is suitable or configured. These components could encompass, for example, mechanical, electrical, optical, pneumatic, hydraulic, and/or software elements.

Throughout this specification, a “control unit” may refer to a device, potentially an electronic device, possessing at least one designated function associated with determining and/or influencing an operational condition, state, or parameter pertaining to another device, unit, or component. A control unit may or may form an integral part of the multifunction control system. Further, a control unit being “configured” to execute a process may refer to the control unit being capable and appropriate for the process. This can be realized in a variety of ways. For instance, the control unit may comprise at least one processor and at least one memory connected to the said processor. The memory may store program code instructions that, upon execution on the processor, prompt the processor to undertake the procedure in question. Memory devices within a control unit may comprise non-transitory computer-readable media, such as physical computer storage including hard drives, solid-state memory, random access memory (RAM), read-only memory (ROM), optical disc, volatile or non-volatile storage, combinations thereof, and the like. Additionally or alternatively, any functionally described attributes of a control unit may be executed, at least partially, by one or more hardware logic components. For example, and without limitation, illustrative types of appropriate hardware logic components include Field Programmable Gate Arrays (FPGAs), Application Specific Integrated Circuits (ASICs), Application Specific Standard Products (ASSPs), System on a Chips (SOCs), Complex Programmable Logic Devices (CPLDs), and so the like. A control unit may generally function according to any suitable principles and via any suitable circuitry and/or signals recognized in the art.

In some embodiments, the presently described methods, devices, and apparatuses may be useful in the fields of microfabrication and nanofabrication. In some embodiments, the presently described methods, devices, and apparatuses may be useful in the fields of microelectromechanical systems, microsystems, photonics, photovoltaics, display devices, and/or semiconductor manufacturing technology. In some embodiments, the presently described methods, devices, and apparatuses may be beneficial for plasma-enhanced atomic layer deposition (PEALD). In some embodiments, they may be applied to manufacturing silicon-based electronics, including memory devices, microprocessors, and sensors. In some embodiments, they may contribute to sustainable manufacturing practices in semiconductor production. In some embodiments, the presently described methods, devices, and apparatuses may be useful for reducing chemical waste and enhancing deposition efficiency in the creation of silicon nitride (SiN) films.

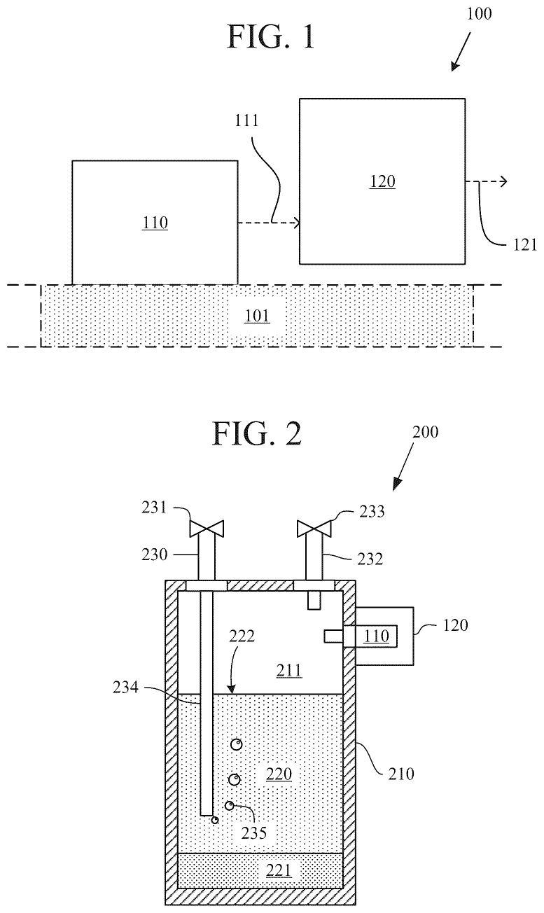

FIG. 1 schematically illustrates a process gas monitoring apparatus 100 for monitoring supply of process gas 101 comprising a chemical substance thermally decomposable to form a decomposition product according to an embodiment. Unless explicitly stated otherwise, the process gas monitoring apparatus 100 of the embodiment of FIG. 1 may or may not comprise any feature(s) disclosed within this specification, mutatis mutandis. Other embodiments may or may not be identical or similar to the embodiment of FIG. 1.

The process gas monitoring apparatus 100 of the embodiment of FIG. 1 comprises a gas analyzer 110 configured to generate a concentration signal 111 indicative of concentration of the decomposition product in the process gas 101. The process gas monitoring apparatus 100 further comprises a process gas control unit 120 configured to receive the concentration signal 111 and to generate a control signal 121 if the concentration of the decomposition product indicated by the concentration signal 111 is greater than a predetermined concentration threshold value. In some embodiments, such a gas analyzer and such a process gas control unit may increase precision and/or accuracy in sensing the degradation of process gas to be fed into a process chamber of a substrate processing apparatus, which may, in turn, enable increasing the overall utilization rate of a chemical substance in the process gas.

FIG. 2 schematically depicts volatilization vessel 200 for holding a chemical substance 220 thermally decomposable to form a decomposition product 221 according to an embodiment. Unless explicitly stated otherwise, the volatilization vessel 200 of the embodiment of FIG. 2 may or may not comprise any feature(s) disclosed within this specification, mutatis mutandis. Other embodiments may or may not be identical or similar to the embodiment of FIG. 2.

The volatilization vessel 200 of the embodiment of FIG. 2 comprises a shell 210 defining an inner cavity 211 for holding the chemical substance 220 in condensed form. The volatilization vessel 200 further comprises a gas analyzer 110 configured to generate a concentration signal indicative of concentration of the decomposition product 221 in the inner cavity 211 and a process gas control unit 120 configured to receive the concentration signal and to generate a control signal if the concentration of the decomposition product indicated by the concentration signal is greater than a predetermined concentration threshold value.

In the embodiment of FIG. 2, the volatilization vessel 200 is implemented as a vaporization vessel. In other embodiments, a volatilization vessel may or may not be implemented as a vaporization vessel.

In the embodiment of FIG. 2, the chemical substance 220 is held in liquid form inside the inner cavity 211, and the volatilization vessel 200 comprises a carrier gas inlet 230 provided with a carrier gas flow control valve 231 as well as a gas outlet 232 provided with a gas outlet flow control valve 233. The volatilization vessel 200 further comprises carrier gas conduit 234 configured to direct carrier gas 235, such as argon or helium, introduced into the volatilization vessel 200 via the carrier gas inlet 230 below a surface 222 of the chemical substance 220 during use of the volatilization vessel 200. In other embodiments, a volatilization vessel for holding a chemical substance thermally decomposable to form a decomposition product may or may not comprise the chemical substance, a carrier gas inlet, a gas outlet, and/or a carrier gas conduit.

In the embodiment of FIG. 2, the decomposition product 221 has a first molecular weight, and the chemical substance 220 has a molecular weight lower than the first molecular weight. In some embodiments, a chemical substance having a molecular weight lower than the first molecular weight of a decomposition product may result in the decomposition product having a density higher than the chemical substance under various environmental conditions, which may, in some cases, result in the decomposition product settling towards a bottom of a volatilization vessel. In other embodiments, wherein a decomposition product has a first molecular weight, and a chemical substance may or may not have a molecular weight lower than the first molecular weight of a decomposition product.

The decomposition product 221 of the embodiment of FIG. 2 has a first density at standard ambient temperature and pressure, e.g., at a temperature of 25° C. and a pressure of 101.325 kPa, and the chemical substance 220 has a density lower than the first density at standard ambient temperature and pressure. In other embodiments, wherein a decomposition product has a first density at standard ambient temperature and pressure, a chemical substance may or may not have a density lower than the first density at standard ambient temperature and pressure.

In the embodiment of FIG. 2, the chemical substance 220 comprises a halogenated silane, for example, diiodosilane. In other embodiments, a chemical substance may or may not comprise a halogenated silane. In some embodiments, a chemical substance comprises silicon and a halogen. In some such embodiments, the chemical substance has a general formula of SiₙH₂ₙ₊₂₋ₘXₘ, wherein X is a halogen, n is from at least 1 to at most 3, and m is from at least 1 to at most 2n+1. In some embodiments, the halogen is selected from F, Cl, Br, and I.

In the embodiment of FIG. 2, also the decomposition product 221 comprises a halogenated silane, for example, triiodosilane. In particular, the decomposition product 221 forms via halogenation of the chemical substance 220. In other embodiments, a decomposition product may or may not comprise a halogenated silane. In other embodiments, a decomposition product may or may not form via halogenation of a chemical substance.

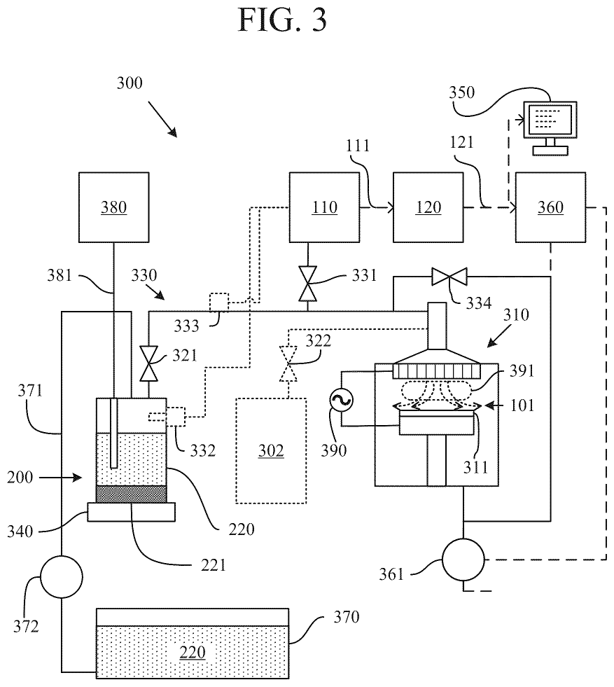

Although not explicitly depicted in FIG. 3, the chemical substance 220 may thermally decompose to form one or more further decomposition products other than the decomposition product 221, for example, via dehalogenation of the chemical substance 220. For example, in case of the chemical substance 220, the one or more further decomposition products may comprise iodosilane, which may have a density lower than that of the chemical substance 220. In other embodiments, a chemical substance may or may not thermally decompose to form one or more further decomposition products other than the decomposition product. In embodiments, wherein a chemical substance thermally decomposes to form one or more further decomposition products other than the decomposition product, the one or more further decomposition products may form via any suitable reaction mechanisms, e.g., via dehalogenation of the chemical substance or the like.

FIG. 3 schematically depicts substrate processing apparatus 300 according to an embodiment. Unless explicitly stated otherwise, the substrate processing apparatus 300 of the embodiment of FIG. 3 may or may not comprise any feature(s) disclosed within this specification, mutatis mutandis. Other embodiments may or may not be identical or similar to the embodiment of FIG. 3.

In the embodiment of FIG. 3, the substrate processing apparatus 300 comprises a process chamber 310 for holding at least part of a substrate 311.

The substrate processing apparatus 300 of the embodiment of FIG. 3 comprises a process gas inlet 321 for receiving process gas 101 from a volatilization vessel 200 as well as a process gas delivery line 330 extending between the process gas inlet 321 and the process chamber 310 for transferring the process gas 101 into the process chamber 310. In the embodiment of FIG. 3, the process gas 101 comprises a chemical substance 220 thermally decomposable to form a decomposition product 221. The substrate processing apparatus 300 further comprises a gas analyzer 110 configured to generate a concentration signal 111 indicative of concentration of the decomposition product 221 in the process gas 101 and a process gas control unit 120 configured to receive the concentration signal 111 and to generate a control signal 121 if the concentration of the decomposition product 221 indicated by the concentration signal 111 is greater than a predetermined concentration threshold value.

In the embodiment of FIG. 3, the substrate processing apparatus 300 comprises the volatilization vessel 200 coupled to the process gas inlet 321. In other embodiments, a substrate processing apparatus may or may not comprise a volatilization vessel coupled to a process gas inlet.

In the embodiment of FIG. 3, the substrate processing apparatus 300 comprises a vessel heater 340 for heating the volatilization vessel 200. In other embodiments, a substrate processing apparatus may or may not comprise such a vessel heater.

The vessel heater 340 of the embodiment of FIG. 3 is configured to maintain temperature of the chemical substance 220 inside the volatilization vessel 200 approximately at 30° C., or at 40° C., or at 50° C., or at 50° C., or at 60° C., or at 70° C. In some embodiments, a vessel heater being configured to maintain temperature of a chemical substance inside a volatilization vessel in a specific temperature range may enable balancing the volatilization and decomposition rates of the chemical substance. In other embodiments, wherein a substrate processing apparatus comprises a vessel heater, the vessel heater may be configured to maintain temperature of a chemical substance inside a volatilization vessel in any suitable temperature range, for example, in a temperature range from 0° C. to 150° C., or from 30° C. to 70° C., or from 40° C. to 100° C., or from 20° C. to 90° C.

In the embodiment of FIG. 3, the gas analyzer 110 is configured to measure the concentration of the decomposition product 221 in the process gas 101 within the process gas delivery line 330 by conducting an on-line decomposition product concentration measurement. In particular, the process gas delivery line 330 of the embodiment of FIG. 3 comprises a process gas sampling valve 331 for directing process gas 101 from the process gas delivery line 330 towards the gas analyzer 110. Sampling of the process gas 101 via the process gas sampling valve 331 may be accomplished in any suitable manner, for example, by repeated, recurrent, intermittent, periodic, or continuous sampling.

In other embodiments, a gas analyzer may be configured to measure the concentration of a decomposition product in a process gas within a process gas delivery line and/or within a volatilization vessel in any suitable manner, for example, by one or more in-line measurements and/or one or more on-line measurements. For example, as schematically illustrated in FIG. 3 using dotted lines, a gas analyzer may in some embodiments comprise a gas sensor 332 functionally coupled with a volatilization vessel for measuring concentration of a decomposition product in a process gas within the volatilization vessel and/or a gas sensor 333 functionally coupled with a process gas delivery line for measuring concentration of the decomposition product in the process gas within the process gas delivery line. In other embodiments, a gas analyzer may additionally or alternatively comprise one or more process gas sampling valves for directing process gas sampled from any suitable positions, for example, from a process gas delivery line and/or from a volatilization vessel towards the gas analyzer, in any suitable manner, for example, by recurrent, intermittent, periodic, or continuous sampling.

The gas analyzer 110 of the embodiment of FIG. 3 may be implemented as a mass spectrometer, such as a residual gas analyzer. In some embodiments, a gas analyzer being implemented as a mass spectrometer may facilitate detecting minute variations in the concentration of a decomposition product in a process gas. In other embodiments, a gas analyzer may be implemented as any suitable manner. For example, in some embodiments, a gas analyzer may comprise a mass spectrometer, an infrared gas analyzer, a thermal conductivity detector, a flame ionization detector, an electron capture detector, a vacuum ultraviolet detector, a helium ionization detector, a photoionization detector, a metal-oxide-semiconductor (MOS) sensor, and/or a pulsed discharge detector.

In the embodiment of FIG. 3, the substrate processing apparatus 300 comprises an alarm control unit 350 configured to receive the control signal 121 and to raise an alarm in response to the control signal 121. In some embodiments, a substrate processing apparatus comprising such an alarm control unit may enable informing an operator of changes in process gas composition, whereby a manual volatilization vessel refilling or change procedure may be initiated if necessary. Additionally or alternatively, a substrate processing apparatus comprising such an alarm control unit may enable initiating an at least partly automated volatilization vessel refilling or change procedure or selecting another volatilization vessel for use by the substrate processing apparatus.

In the embodiment of FIG. 3, the process gas delivery line comprises a process gas bypass valve 334 for steering the process gas 101 past the process chamber 310, the substrate processing apparatus 300 comprises a vessel unload control unit 360 operatively coupled with the process gas bypass valve 334 and configured to receive the control signal 121, and the vessel unload control unit 360 is configured to hold the process gas bypass valve 334 open in response to the control signal 121 for emptying the volatilization vessel 200. In some embodiments, such an arrangement may enable automatically removing at least part of any decomposition product accumulated inside a volatilization vessel with limited contamination of a process chamber. In other embodiments, a process gas delivery line may or may not comprise such a process gas bypass valve and/or a vessel unload control unit. In other embodiments, wherein an at least partly automated volatilization vessel emptying procedure is initiated in response to a control signal, the at least partly automated volatilization vessel emptying procedure may be conducted in any suitable manner.

The substrate processing apparatus 300 of the embodiment of FIG. 3 further comprises an exhaust pump 361 fluidically coupled with the process chamber 310 for evacuating the process chamber 310 and fluidically coupled with the process gas bypass valve 334 for driving the process gas 101 past the process chamber 310, and the vessel unload control unit 360 is operatively coupled with the exhaust pump 361 and configured to maintain the exhaust pump 361 active in response to the control signal 121 for emptying the volatilization vessel 200. In other embodiments, wherein a process gas delivery line comprises a process gas bypass valve and a vessel unload control unit, a substrate processing apparatus may or may not such an exhaust pump operatively coupled with the vessel unload control unit in such a manner.

In the embodiment of FIG. 3, the substrate processing apparatus 300 comprises a storage vessel 370 for storing the chemical substance 220 in condensed form and a refill line 371 fluidically coupled with the storage vessel 370 for transferring the chemical substance 220 from the storage vessel 370 to the volatilization vessel 200. In some embodiments, a substrate processing apparatus comprising such a storage vessel and refill line may facilitate refilling a volatilization vessel after a manual or an at least partly automated volatilization vessel emptying procedure. In other embodiments, a substrate processing apparatus may or may not comprise such a storage vessel and/or such a refill line.

The substrate processing apparatus 300 of the embodiment of FIG. 3 further comprises a refill pump 372 configured for transporting the chemical substance 220 from the storage vessel 370 to the volatilization vessel 200 in liquid form. In other embodiments, wherein a substrate processing apparatus comprises a storage vessel and a refill line, the substrate processing apparatus may or may not comprise a refill pump configured for transporting a chemical substance from the storage vessel to a volatilization vessel in liquid form. For example, in some embodiments, a substrate processing apparatus may comprise a refill line configured for transporting a chemical substance from the storage vessel to a volatilization vessel in gaseous form.

The substrate processing apparatus 300 of the embodiment of FIG. 3 is specifically implemented as a temporal atomic layer deposition apparatus. In other embodiments, a substrate processing apparatus may be implemented in any suitable manner, for instance, as a dry etching apparatus or a vacuum deposition apparatus, such as a chemical vapor deposition apparatus, for example, a cyclic chemical vapor deposition apparatus, such as an atomic layer deposition apparatus, e.g., a temporal atomic layer deposition apparatus.

In the embodiment of FIG. 3, the substrate processing apparatus 300 comprises a carrier gas supply 380 and a carrier gas line 381 extending between the carrier gas supply 380 and the volatilization vessel 200 for supplying carrier gas to the volatilization vessel 200. In other embodiments, a substrate processing apparatus may or may not comprise such a carrier gas supply and/or such a carrier gas line.

As indicated in FIG. 3 using dotted lines, the substrate processing apparatus 300 of the embodiment of FIG. 3 may further comprise a second process gas inlet 322 for receiving process gas 101 from a second volatilization vessel 302. In some embodiments, a substrate processing apparatus comprising such a second process gas inlet may enable uninterrupted operation of the substrate processing apparatus while a volatilization vessel coupled to a process gas inlet is emptied and/or refilled. In other embodiments, a substrate processing apparatus may comprise any suitable number, e.g., one, or two, or three, or four, etc., of process gas inlets for receiving process gas from any suitable number of volatilization vessels. What is stated throughout this disclosure about the features of volatilization vessels, such as the volatilization vessel 200 of the embodiment of FIG. 2, and their interoperability with any part(s) of substrate processing apparatuses, such as the substrate processing apparatus 300 of the embodiment of FIG. 3, may apply also to any further volatilization vessels, mutatis mutandis. Similarly, what is stated throughout this disclosure about the features of process gas inlets, such as the process gas inlet 321 of the embodiment of FIG. 3, and their interoperability with any other part(s) of substrate processing apparatuses, such as the substrate processing apparatus 300 of the embodiment of FIG. 3, may apply also to any further process gas inlets, mutatis mutandis.

In the embodiment of FIG. 3, the substrate processing apparatus 300 comprises an active species generation unit 390 for supplying active species into the process chamber 310. The active species generation unit 390 of the embodiment of FIG. 3 is specifically implemented as an in-situ plasma generation unit for producing a plasma 391 in the process chamber 310. This allows using active species, such as active species formed by exposing a mixture of hydrogen and nitrogen gases to the plasma 391, to affect film deposition by the substrate processing apparatus 300. In other embodiments, a substrate processing apparatus may or may not comprise an active species generation unit. In embodiments, wherein a substrate processing apparatus comprises an active species generation unit, the active species generation unit may be implemented using any suitable technology, for example, as an in-situ plasma generation unit or a remote plasma generation unit.

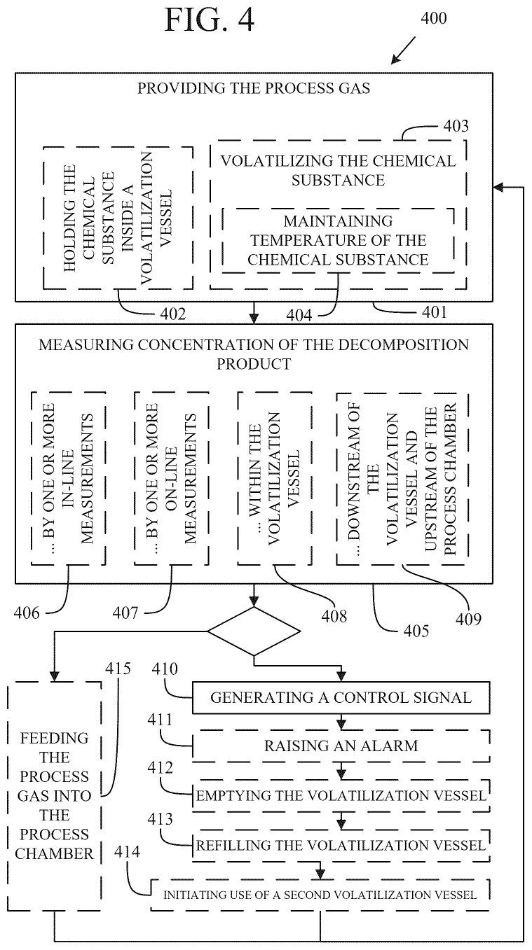

FIG. 4 schematically depicts method 400 for monitoring supply of process gas into a process chamber according to an embodiment. Unless explicitly stated otherwise, the method 400 of the embodiment of FIG. 4 may or may not comprise any feature(s) disclosed within this specification, mutatis mutandis. Other embodiments may or may not be identical or similar to the embodiment of FIG. 4.

In the embodiment of FIG. 4, the process gas comprises a chemical substance thermally decomposable to form a decomposition product, and the method 400 comprises providing the process gas 401 to be supplied into the process chamber, measuring concentration of the decomposition product 405 in the process gas, and generating a control signal 410 if the concentration of the decomposition product is greater than a predetermined concentration threshold value.

As indicated in FIG. 4 using dashed lines, the process of providing the process gas 401 of the embodiment of FIG. 4 may comprise holding the chemical substance inside a volatilization vessel 402 and volatilizing the chemical substance 403 to form the process gas. In other embodiments, a method for monitoring supply of process gas into a process chamber may or may not comprise holding the chemical substance inside a volatilization vessel and/or volatilizing the chemical substance.

In the embodiment of FIG. 4, the process of volatilizing the chemical substance 403 may comprise maintaining temperature of the chemical substance 404 in a temperature range from 0° C. to 150° C., as indicated in FIG. 4 using dashed lines. In other embodiments, a process of volatilizing the chemical substance may or may not comprise maintaining temperature of the chemical substance in a specific temperature range. In some embodiments, a process of volatilizing the chemical substance may comprise maintaining temperature of the chemical substance in a temperature range from 0° C. to 150° C., or from 30° C. to 70° C., or from 40° C. to 100° C., or from 20° C. to 90° C.

As again indicated using dashed lines, the process of measuring concentration of the decomposition product 405 of the embodiment of FIG. 4 may comprise measuring the concentration of the decomposition product by one or more in-line measurements 406 and/or measuring the concentration of the decomposition product by one or more on-line measurements 407. In other embodiments, a process of measuring concentration of the decomposition product may or may not comprise measuring the concentration of the decomposition product by one or more in-line measurements and/or measuring the concentration of the decomposition product by one or more on-line measurements.

Similarly, the process of measuring concentration of the decomposition product 405 of the embodiment of FIG. 4 may further comprise measuring the concentration of the decomposition product within the volatilization vessel 408 and/or measuring the concentration of the decomposition product downstream of the volatilization vessel and upstream of the process chamber 409. In other embodiments, a process of measuring concentration of the decomposition product may or may not comprise measuring the concentration of the decomposition product within the volatilization vessel and/or measuring the concentration of the decomposition product downstream of the volatilization vessel and upstream of the process chamber.

As again indicated in FIG. 4 using dashed lines, the method 400 may comprise raising an alarm 411 in response to the control signal, emptying the volatilization vessel 412 in response to the control signal, refilling the volatilization vessel 413, and/or initiating use of a second volatilization vessel 414 for supplying process gas into the process chamber in response to the control signal. In other embodiments, a method for monitoring supply of process gas into a process chamber may or may not comprise raising an alarm, emptying the volatilization vessel, refilling the volatilization vessel, and/or initiating use of a second volatilization vessel in response to a control signal.

Further, as once more indicated using dashed lines, the method 400 may comprise feeding the process gas into the process chamber 415 if the concentration of the decomposition product is less than or equal to the predetermined concentration threshold value. In other embodiments, a method for monitoring supply of process gas into a process chamber may or may not comprise feeding the process gas into the process chamber.

The method 400 of the embodiment of FIG. 4 may be implemented as a continuous process, wherein the processes of providing the process gas 401 and measuring concentration of the decomposition product 405 are run in parallel. In such case, the concentration of the decomposition product may be measured, for example, repeatedly, recurrently, intermittently, periodically, or continuously, and process gas may be fed into the process chamber until a concentration exceeding the predetermined concentration threshold value is measured. Once a concentration exceeding the predetermined concentration threshold value is measured, the process gas nay be diverted away from process chamber, the use of the volatilization vessel for producing process gas may be discontinued, the use of second volatilization vessel may be initiated to reduce process downtime, and the volatilization vessel may be emptied and refilled while process gas comprising chemical substance originating from the second volatilization vessel is used.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A process gas monitoring apparatus for monitoring supply of process gas comprising a chemical substance thermally decomposable to form a decomposition product, the process gas monitoring apparatus comprising:
a gas analyzer configured to generate a concentration signal indicative of concentration of the decomposition product in the process gas, and
a process gas control unit configured to receive the concentration signal and to generate a control signal if the concentration of the decomposition product indicated by the concentration signal is greater than a predetermined concentration threshold value.

2. A volatilization vessel for holding a chemical substance thermally decomposable to form a decomposition product, the volatilization vessel comprising:
a shell defining an inner cavity for holding the chemical substance in condensed form,
a gas analyzer configured to generate a concentration signal indicative of concentration of the decomposition product in the inner cavity, and
a process gas control unit configured to receive the concentration signal and to generate a control signal if the concentration of the decomposition product indicated by the concentration signal is greater than a predetermined concentration threshold value.

3. A volatilization vessel according to claim 2 implemented as a vaporization vessel.

4. A volatilization vessel according to claim 2, wherein the volatilization vessel comprises the chemical substance, the chemical substance held in the inner cavity.

5. A volatilization vessel according to claim 4, wherein the decomposition product has a first molecular weight, and the chemical substance has a molecular weight lower than the first molecular weight.

6. A volatilization vessel according to claim 4, wherein the chemical substance comprises a halogenated silane.

7. A substrate processing apparatus, comprising:
a process chamber for holding at least part of a substrate;
a process gas inlet for receiving process gas from a volatilization vessel;
a process gas delivery line extending between the process gas inlet and the process chamber for transferring the process gas into the process chamber, the process gas comprising a chemical substance thermally decomposable to form a decomposition product;
a gas analyzer configured to generate a concentration signal indicative of concentration of the decomposition product in the process gas; and
a process gas control unit configured to receive the concentration signal and to generate a control signal if the concentration of the decomposition product indicated by the concentration signal is greater than a predetermined concentration threshold value.

8. A substrate processing apparatus according to claim 7, wherein the substrate processing apparatus comprises a vessel heater for heating the volatilization vessel.

9. A substrate processing apparatus according to claim 8, wherein the vessel heater is configured to maintain temperature of the chemical substance inside the volatilization vessel in a temperature range from 0° C. to 150° C.

10. A substrate processing apparatus according to claim 7, wherein the gas analyzer is configured to measure the concentration of the decomposition product in the process gas within the process gas delivery line.

11. A substrate processing apparatus according to claim 7, wherein the gas analyzer is configured to measure the concentration of the decomposition product in the process gas within the volatilization vessel.

12. A substrate processing apparatus according to claim 7, wherein the gas analyzer is configured to measure the concentration of the decomposition product by one or more in-line measurements and/or one or more on-line measurements.

13. A substrate processing apparatus according to claim 7, wherein the substrate processing apparatus comprises an alarm control unit configured to receive the control signal and to raise an alarm in response to the control signal.

14. A substrate processing apparatus according to claim 7, wherein the process gas delivery line comprises a process gas bypass valve for steering the process gas past the process chamber, the substrate processing apparatus comprises a vessel unload control unit operatively coupled with the process gas bypass valve and configured to receive the control signal, and the vessel unload control unit is configured to hold the process gas bypass valve open in response to the control signal for emptying the volatilization vessel.

15. A substrate processing apparatus according to claim 7, wherein the substrate processing apparatus comprises a storage vessel for storing the chemical substance in condensed form and a refill line fluidically coupled with the storage vessel for transferring the chemical substance from the storage vessel to the volatilization vessel.

16. A substrate processing apparatus according to claim 7, wherein the substrate processing apparatus comprises a second process gas inlet for receiving process gas from a second volatilization vessel.

17. A substrate processing apparatus according to claim 7 implemented as a vacuum deposition apparatus, such as a chemical vapor deposition apparatus, for example, a cyclic chemical vapor deposition apparatus, such as an atomic layer deposition apparatus, e.g., a temporal atomic layer deposition apparatus.

18. A method for monitoring supply of process gas into a process chamber, the method comprising:
providing the process gas to be supplied into the process chamber, the process gas comprising a chemical substance thermally decomposable to form a decomposition product;
measuring concentration of the decomposition product in the process gas; and
generating a control signal if the concentration of the decomposition product is greater than a predetermined concentration threshold value.

19. A method according to claim 18, wherein providing the process gas comprises holding the chemical substance inside a volatilization vessel and volatilizing the chemical substance to form the process gas.

20. A method according to claim 19, wherein volatilizing the chemical substance comprises maintaining temperature of the chemical substance in a temperature range from 0° C. to 150° C.

21. A method according to claim 18, wherein measuring concentration of the decomposition product comprises measuring the concentration of the decomposition product by one or more in-line measurements and/or measuring the concentration of the decomposition product by one or more on-line measurements.

22. A method according to claim 18, wherein measuring concentration of the decomposition product comprises measuring the concentration of the decomposition product within the volatilization vessel.

23. A method according to claim 18, wherein measuring concentration of the decomposition product comprises measuring the concentration of the decomposition product downstream of the volatilization vessel and upstream of the process chamber.

24. A method according to claim 18, wherein the method comprises raising an alarm in response to the control signal.

25. A method according to claim 18, wherein the method comprises emptying the volatilization vessel in response to the control signal.

26. A method according to claim 18, wherein the method comprises refilling the volatilization vessel in response to the control signal.

27. A method according to claim 18, wherein the method comprises initiating use of a second volatilization vessel for supplying process gas into the process chamber in response to the control signal.

28. A method according to claim 18, wherein the method comprises feeding the process gas into the process chamber if the concentration of the decomposition product is less than or equal to the predetermined concentration threshold value.
